(19) United States
(12) Patent Application Publication
(10) Pub. No.: US 2019/0252325 A1
(43) Pub. Date: Aug. 15, 2019

(54) CHIP PACKAGE STRUCTURE AND MANUFACTURING METHOD THEREOF

(71) Applicant: Powertech Technology Inc., Hsinchu County (TW)

(72) Inventors: Yu-Wei Chen, Hsinchu County (TW); Hsuan-Chih Chang, Hsinchu County (TW); Yuan-Fu Lan, Hsinchu County (TW); Hsien-Wen Hsu, Hsinchu County (TW)

(73) Assignee: Powertech Technology Inc., Hsinchu County (TW)

(21) Appl. No.: 16/035,709

(22) Filed: Jul. 16, 2018

(30) Foreign Application Priority Data
Feb. 9, 2018 (TW) 107104587

(51) Int. Cl. H01L 23/552; H01L 23/31; H01L 23/538; H01L 23/00; H01L 21/48; H01L 21/56; H01L 21/683

(52) U.S. Cl. CPC H01L 23/552; H01L 2924/3025; H01L 23/5383; H01L 23/5386; H01L 23/5389; H01L 24/20; H01L 24/19; H01L 21/4857; H01L 21/4853; H01L 21/565; H01L 21/6835; H01L 2221/68372; H01L 2224/214; H01L 2924/1434; H01L 2924/1431; H01L 2924/19041; H01L 2924/19106; H01L 23/3135

(57) ABSTRACT

A chip package structure including a first circuit structure, a chip, an electronic device, a first encapsulant, a second encapsulant, a plurality of through pillars, and an electromagnetic interference (EMI) shielding layer is provided. The chip has an active surface facing the first circuit structure. The electronic device has a connection surface facing the first circuit structure. The chip and the electronic device are disposed on opposite sides of the first circuit structure respectively. The first encapsulant encapsulates the chip. The second encapsulant encapsulates the electronic device. The through pillars penetrate the first encapsulant and are electrically connected to the first circuit structure. The EMI shielding layer covers the first encapsulant and the second encapsulant. The chip or the electronic device is grounded by the EMI shielding layer.

### CROSS-REFERENCE TO RELATED APPLICATION

This application claims the priority benefit of Taiwan application serial no. 107104587, filed on Feb. 9, 2018. The entirety of the above-mentioned patent application is hereby incorporated by reference herein and made a part of this specification.

### BACKGROUND OF THE INVENTION

### Field of the Invention

The invention relates to a package structure, and particularly relates to a chip package structure.

### Description of Related Art

Along with development of technology, the demand on electronic products in the market is also increasing toward a trend of lightness, slimness, shortness and smallness. In order to satisfy the above demand, electronic devices of different types may be integrated in a single package to form a system in a package (SIP).

In today's chip package structure, chips are electrically connected to a Printed Circuit Board (PCB) through bondwires or bumps, so that electronic signals may be transmitted between the chips and the PCB or between the chips. However, some chips, for example, a communication chip may produce Electromagnetic Interference (EMI) to influence operations of other chips (for example, a data storage chip) in the chip package structure, so that the process of electronic signal transmission between the chips is accompanied by noises, which influences a normal operation of the chip. Besides, under consideration of Power Integrity (PI), it is required to provide a stable voltage to the chips in the package structure, especially when chips of different functions simultaneously operate in the chip package structure.

In order to maintain the PI of the chip package structure, a commonly used method is to set a Decoupling Capacitor (De-Cap) in the chip package structure. However, limited by a size of the De-Cap, a volume of the chip package structure is increased, so that a design demand of miniaturization cannot be satisfied. Therefore, under the premise of satisfying the design demand of miniaturizing the chip package structure, how to improve a spatial usage rate of the chip package structure and effectively integrate the electronic devices of different types in the chip package structure and meanwhile achieve an effect of EMI prevention and maintain the PI of the chip package structure is one of the problems to be resolved in the field.

### SUMMARY OF THE INVENTION

The invention provides a chip package structure and a manufacturing method thereof, which are adapted to improve a spatial usage rate of the chip package structure and effectively integrate electronic devices of different types in the chip package structure.

The invention provides a chip package structure including a first circuit structure, a chip, an electronic device, a first encapsulant, a second encapsulant, a plurality of through pillars, and an electromagnetic interference (EMI) shielding layer. The chip has an active surface facing the first circuit structure. The electronic device has a connection surface facing the first circuit structure. The chip and the electronic device are disposed on two opposite sides of the first circuit structure respectively. The first encapsulant encapsulates the chip. The second encapsulant encapsulates the electronic device. The through pillars penetrate the first encapsulant and are electrically connected to the first circuit structure. The EMI shielding layer covers the first encapsulant and the second encapsulant. The chip or the electronic device is grounded by the EMI shielding layer.

The invention provides a method for manufacturing a chip package structure including at least following steps; providing a first circuit structure, wherein the first circuit structure has a plurality of through pillars; disposing a chip on the first circuit structure, wherein the chip has an active surface facing the first circuit structure, and the chip and the through pillars are disposed on a same side of the first circuit structure; forming a first encapsulant to encapsulate the chip and the through pillars; disposing an electronic device on the first circuit structure, wherein the electronic device has a connection surface facing the first circuit structure, and the electronic device and the chip are disposed on two opposite sides of the first circuit structure; forming a second encapsulant to encapsulate the electronic device; and forming an EMI shielding layer to cover the first encapsulant and the second encapsulant, where the chip or the electronic device is grounded by the EMI shielding layer.

According to the above description, in the chip package structure of the invention, the EMI shielding layer is adapted to prevent the EMI from influencing operations of the internal chips, so as to reduce a degree that the EMI influences the chips in operation. Moreover, the chip package structure of the invention may improve a spatial usage rate and effectively integrate the electronic devices of different types. Besides, the manufacturing method of the chip package structure of the invention may effectively improve reliability of the chip package structure and has lower manufacturing cost.

To make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1L are schematic diagrams of a manufacturing process of a chip package structure according to an embodiment of the invention.

FIG. 2A to FIG. 2C are schematic diagrams of a manufacturing process of a chip package structure according to another embodiment of the invention.

### DESCRIPTION OF EMBODIMENTS

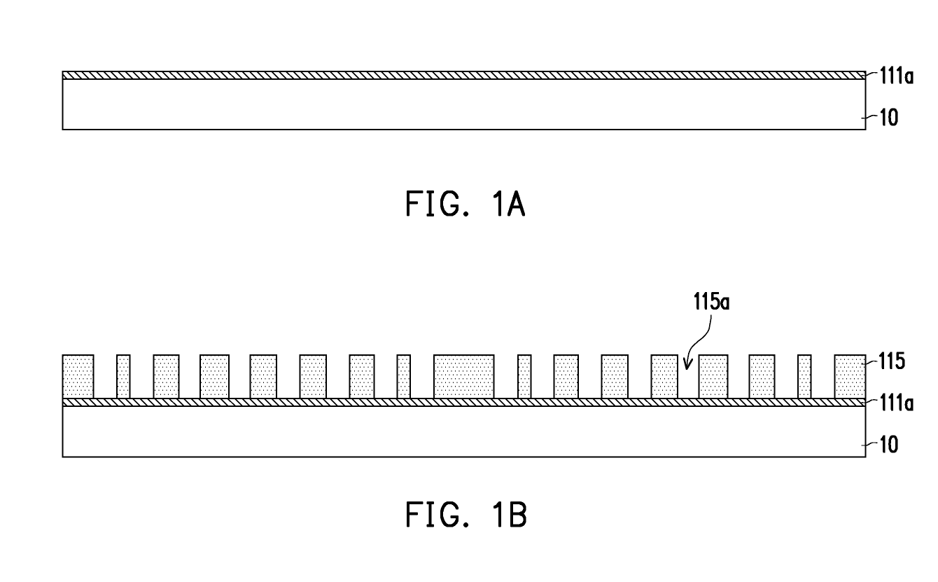

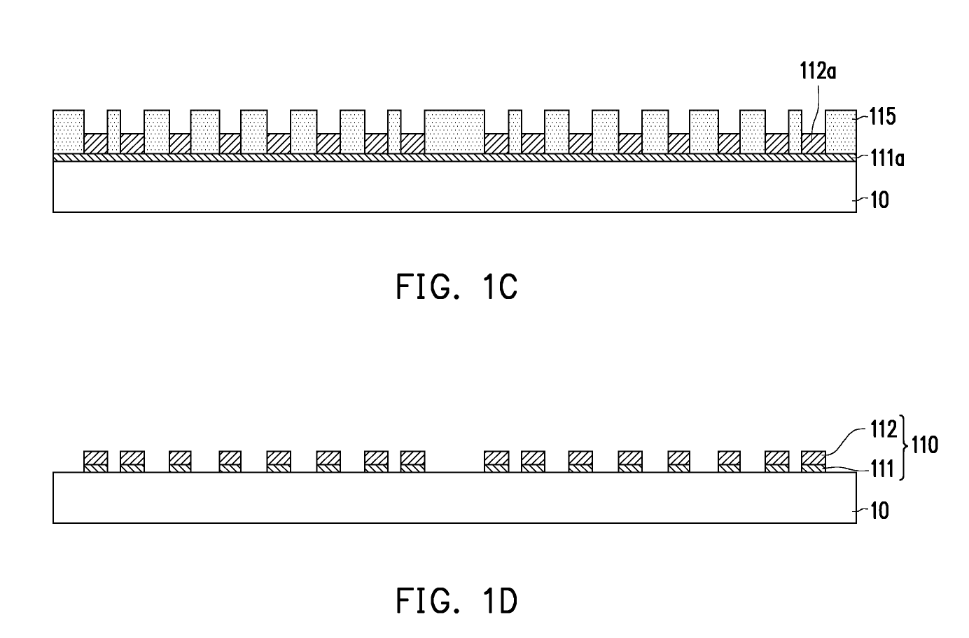

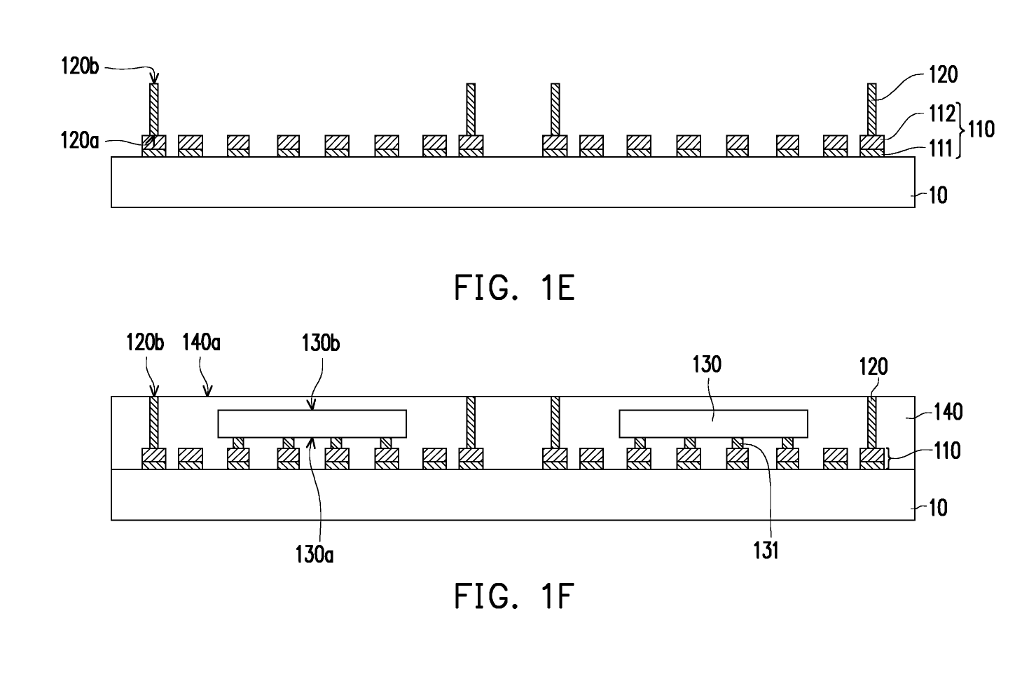

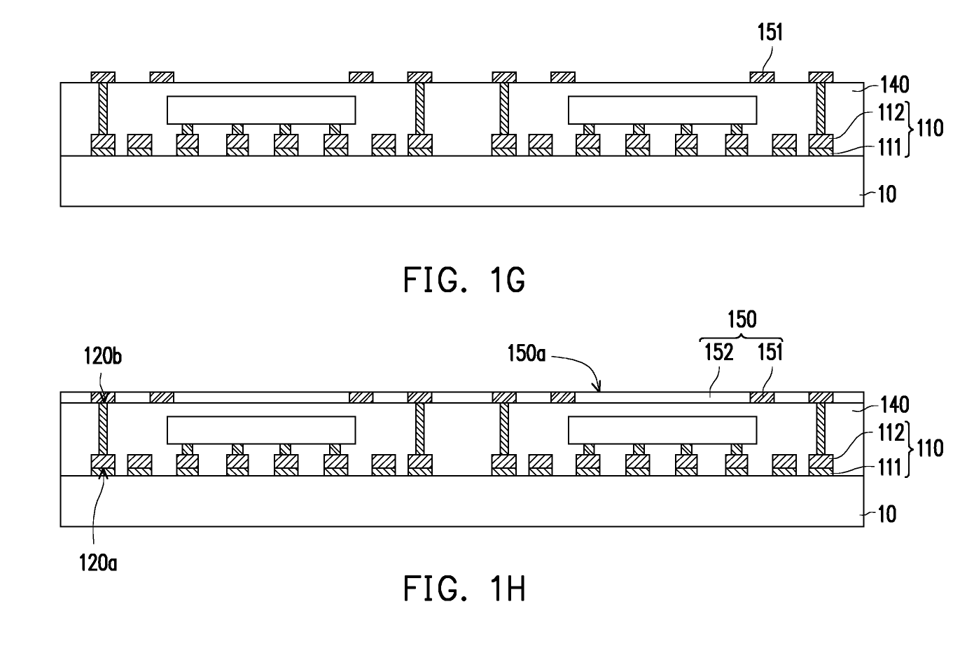

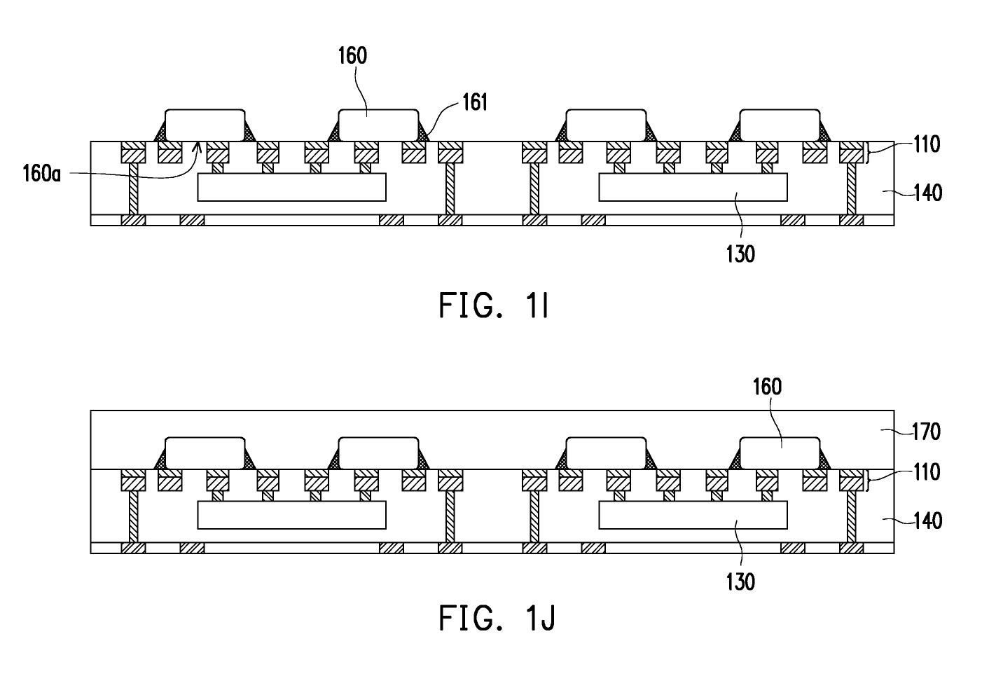

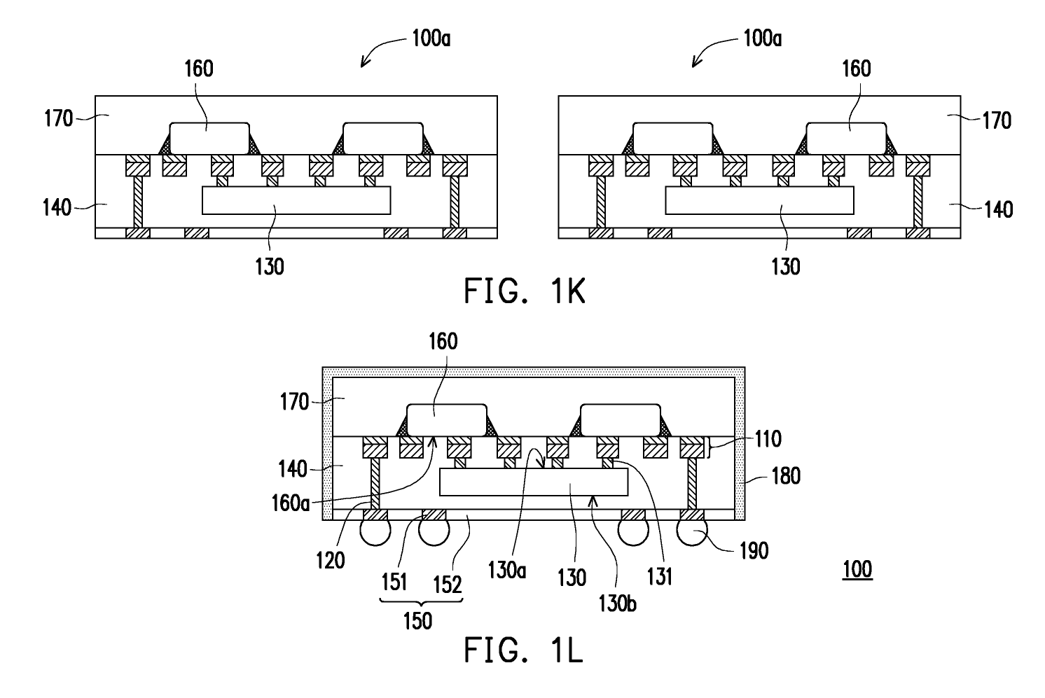

FIG. 1A to FIG. 1L are schematic diagrams of a manufacturing process of a chip package structure according to an embodiment of the invention.

Referring to FIG. 1A, a carrier board 10 is provided. The carrier board 10 may be a silicon substrate, an organic substrate, a ceramic substrate, a dielectric substrate, a laminate substrate or other suitable substrate. In some embodiments, a release film (not shown) may be disposed on the carrier board 10 such that a first circuit structure 110 and/or a first encapsulant 140 disposed on the carrier board 10 may be subsequently separated from the carrier board 10.

A conductive material may be disposed on the carrier board 10 conductive layer 111a through a Physical Vapour Deposition (PVD) or a Chemical Vapour Deposition (CVD) to form a conductive layer 111a. The first conductive layer 111a may be a seed layer. The first conductive layer 111a may include a titanium layer and/or a copper layer, but the invention is not limited thereto.

Referring to FIG. 1B, a mask layer 115 having a plurality of openings 115a may be formed on the first conductive layer 111a. The mask layer 115 may be a patterned photoresist layer formed through a photolithography process. To form the mask layer 115, a layer of photoresist material may be formed to cover on the carrier board 10 first. A part of the photoresist material may then be removed through the photolithography process to form the openings 115a. But, the invention is not limited thereto. In other embodiment, the mask layer 115 may be a hard mask.

Referring to FIG. 1C, after the mask layer 115 is formed on the carrier board 10, a second conductive layer 112a is formed in the openings 115a and on the first conductive layer 111a. The second conductive layer 112a may be formed through an electroplating method or other similar plating method. A material of the second conductive layer 112a may be similar to a material of the first conductive layer 111a, though the invention is not limited thereto.

Referring to FIG. 1C and FIG. 1D, after the second conductive layer 112a is formed, the mask layer 115 is removed. Then, the second conductive layer 112a is used as a mask to remove a part of the first conductive layer 111a not covered by the second conductive layer 112a to form a pattern on the first conductive layer 111. A plasma ashing method or an etching method may be used to remove the mask layer 115, though the invention is not limited thereto. When the etching method is used to remove a portion of the first conductive layer 111a, a part of the second conductive layer 112a may also be removed.

In FIG. 1D, the first circuit structure 110 may comprise the first conductive layer 111 and the second conductive layer 112 disposed on the carrier board 10. The first conductive layer 111 and the second conductive layer 112 of the first circuit structure 110 may substantially have corresponding conductive patterns. The thickness of the second conductive layer 112 may be less than the thickness of the conductive layer 112a (shown in FIG. 1C).

In some embodiments, a dielectric layer and/or a conductive layer may be further formed on the carrier board 10. The first circuit structure 110 may be a redistribution layer (RDL) having a plurality of conductive layers and/or dielectric layers.

Referring to FIG. 1E, a plurality of through pillars 120 are formed on the first circuit structure 110. The through pillars 120 may be conductive pillars formed on the first circuit structure 110 through the electroplating method or other similar plating method. In some embodiment, the through pillars 120 may be integrally formed conductive pillars. In some other embodiments, the through pillars 120 may be bonding wires bonded to the first circuit structure 110. Each through pillar 120 may have a first end 120a and a second end 120b opposite to the first end 120a. A cross-sectional area of the first end 120a may be substantially equal to a cross-sectional area of the second end 120b. The first end 120a may be electrically connected to the first circuit structure 110.

Referring to FIG. 1F, chips 130 may be disposed on the first circuit structure 110. The chip 130 may be disposed on a same side of the first circuit structure 110 as the through pillars 120 through first terminals 131 via a flip-chip bonding method. An active surface 130a of the chip 130 faces the first circuit structure 110. The first terminals 131 may include copper bumps, nickel and tin silver alloy bumps or other suitable conductive bumps, though the invention is not limited thereto. In other embodiments, the first terminals 131 may also include copper pillars, tin silver alloy bumps on the copper pillars, and a nickel layer disposed between the copper pillars and the tin silver alloy bumps.

After the chips 130 are disposed, a first encapsulant 140 is formed to encapsulate the chips 130 and the through pillars 120. The first encapsulant 140 may include a molding compound, an adhesive, or a photoresist. A material of the first encapsulant 140 may include epoxy or polyimide (PI), though the invention is not limited thereto.

In some embodiments, a grinding process or an etching process may be performed to the first encapsulant 140 until the second ends 120b of the through pillars 120 are exposed. A top surface 140a of the first encapsulant 140 and the second ends 120b of the through pillars 120 may be coplanar.

Referring to FIG. 1G, a third conductive layer 151 is formed on the first encapsulant 140. A method for forming the third conductive layer 151 is similar to the method of forming the second conductive layer 112, and detail thereof is not repeated.

Referring to FIG. 1H, after the third conductive layer 151 is formed, a dielectric layer 152 may be formed on the first encapsulant 140. A material of the dielectric layer 152 may be similar to the material of the first encapsulant 140, though the invention is not limited thereto. In some embodiments, the material of the dielectric layer 152 may include silicon oxide, silicon nitride, silicon carbide, silicon oxynitride, or other suitable dielectric material.

In some embodiments, a grinding process may be performed to the dielectric layer 152 and the third conductive layer 151. The third conductive layer 151 and the dielectric layer 152 may be coplanar. The electronic devices 160 may be disposed on a common plane 150a of the third conductive layer 151 and the dielectric layer 152.

The first encapsulant 140 may cover a back surface 130b of the chip 130. The third conductive layer 151 may be overlapped with the chip 130. The density and the flexibility of the layout of the chip package structure 100 may be improved.

In FIG. 1H, a second circuit structure 150 may comprise of the third conductive layer 151 and the dielectric layer 152 disposed on the first encapsulant 140. In some embodiments, the second circuit structure 150 may be a redistribution layer (RDL) having a plurality of conductive layers and a plurality of dielectric layers. The first circuit structure 110 and the second circuit structure 150 are disposed at two opposite ends of the through pillars 120. The first circuit structure 110 and the second circuit structure 150 are connected to the first ends 120a and the second ends 120b of the through pillars 120, respectively.

Before the electronic devices 160 are disposed on the first circuit structure 110, the carrier board 10 may be removed from the first circuit structure 110 and the first encapsulant 140.

Referring to FIG. 1I, the structure shown in FIG. 1H is flipped upside down. The electronic devices 160 is disposed on the first circuit structure 110 and the first encapsulant 140. A connection surface 160a of each electronic device 160 may have electrical contacts. The step of flipping the structure upside down may be performed before or after the step of removing the carrier board 10. In some embodiments, the electronic devices 160 may be disposed on the first circuit structure 110 via a Surface Mount Technology (SMT). The connection surface 160a of each electronic device 160 faces the first circuit structure 110. The chips 130 and the electronic devices 160 are disposed at two opposite sides of the first circuit structure 110. In some embodiments, the chips may be overlapped with the electronic devices 160. The spatial usage rate of the chip package structure 100 may be improved.

In the present embodiment, an underfill 161 may be formed between the electronic devices 160 and the first circuit structure 110. The adhesion between the electronic devices 160 and the first circuit structure 110 may be improved.

The chips 130 and the electronic devices 160 may be homogeneous with each other or heterogeneous with each other, which is not limited by the invention. The chip 130 may be a memory chip, a logic chip or a communication chip. The electronic device 160 may be a Decoupling Capacitor (De-Cap), a chip scale package/chip size package (CSP), or a passive component. In some embodiments, the number of the electronic devices 160 may be plural, and the plurality of electronic devices 160 may be heterogeneous.

Then, referring to FIG. 1J, a second encapsulant 170 is formed on the first circuit structure 110 and the electronic devices 160. A material of the second encapsulant 170 and a forming method thereof are similar to that of the first encapsulant 140, and detail thereof is not repeated. In some embodiments, since the first circuit structure 110 may expose a part of the first encapsulant 140. The second encapsulant 170 formed on the first circuit structure 110 may contact the first encapsulant 140.

Referring to FIG. 1K, a singulation process may be performed to form the package structure 100a. The first encapsulant 140 and the second encapsulant 170 between the adjacent chips 130 may be cut to form a plurality of package structures 100a. The singulation process may include a cutting process through a rotary blade or a laser beam.

Referring to FIG. 1L, a conductive material may be disposed on the second encapsulant 170 through a PVD method or a CVD method to form an electromagnetic interference (EMI) shielding layer 180. The EMI shielding layer 180 covers an outer surface of the first encapsulant 140, an outer surface of the second encapsulant 170, and sidewalls of the second circuit structure 150. The chips 130 and the electronic devices 160 may be disposed within an accommodating space of the EMI shielding layer 180. On other cross-section, the EMI shielding layer 180 may be electrically connected to a part of the third conductive layer 151. The chip 130 or the electronic device 160 is grounded by the EMI shielding layer 180. The EMI shielding effectiveness may be improved via the EMI shielding layer 180.

After the second encapsulant 170 is formed, a plurality of conductive terminals 190 may be formed on the second circuit structure 150. The conductive terminals 190 may be electrically connected to the chips 130 and the electronic devices 160 through the second circuit structure 150, the through pillars 120 and the first circuit structure 110. The conductive terminals 190 may be solder balls, bumps, conductive pillars, bonding wires or a combination thereof arranged in an array. In some embodiment, the conductive terminals 190 and the second circuit structure 150 may have an under bump metallurgy (UBM) pattern there between.

After the aforementioned processes, the manufacturing of the chip package structure 100 of the present embodiment is substantially completed. Referring to FIG. 1L, the chip package structure 100 includes the first circuit structure 110, the chips 130, the electronic devices 160, the first encapsulant 140, the second encapsulant 170, a plurality of the through pillars 120 and the EMI shielding layer 180. The chip 130 has the active surface 130a facing the first circuit structure 110. The electronic device 160 has the connection surface 160a facing the first circuit structure 110. The chip 1130 and the electronic device 160 are correspondingly disposed on two opposite sides of the first circuit structure 110. The first encapsulant 140 encapsulates the chip 130. The second encapsulant 170 encapsulates the electronic device 160. The through pillars 120 penetrate the first encapsulant 140 and are electrically connected to the first circuit structure 110. The EMI shielding layer 180 covers the first encapsulant 140 and the second encapsulant 170. The chip 130 or the electronic device 160 is grounded through the EMI shielding layer 180. In some embodiments, the through pillars 120 may surround the chip 130, though the invention is not limited thereto.

The chip 130 and the electronic device 160 may be electrically connected with each other through the first circuit structure 110. In the chip package structure 100, a distance between the active surface 130a and the connection surface 160a may be 50 μm to 500 μm. Compared to electrically connecting through a printed circuit board (PCB), a wiring length for the electrical connection between the chip 130 and the electronic device 160 of the chip package structure 100 may be shorter. The operation speed of the chip package structure 100 may be improved.

In some embodiments, the first circuit structure 110 may have a plurality of meander lines. The first encapsulant 140 or the second encapsulant 170 may be filled between the adjacent meander lines. Lines of the first circuit structure 110 may be separated from each other by the first encapsulant 140 or the second encapsulant 170. The overall thickness of the chip package structure 100 may be reduced.

For the chip package structure 100, since the through pillars 120 penetrates through the first encapsulant 140, a laser drilling process may be omitted and reduced the manufacturing cost. Damage on the first circuit structure 110 caused by laser may be avoided. Laser drilling process resulting with low process window may be avoided. Moreover, the through pillars 120 of the chip package structure 100 are solid pillars formed on the first circuit structure 110. The through pillars 120 of the chip package structure 100 may have better electrical property. A distance between any two adjacent through pillars 120 may be reduced. Whereas, the through holes formed through the laser drilling process may be conical pillars with voids inside. The chip package structure 100 of the present embodiment may have better reliability, lower production cost and thinner overall thickness.

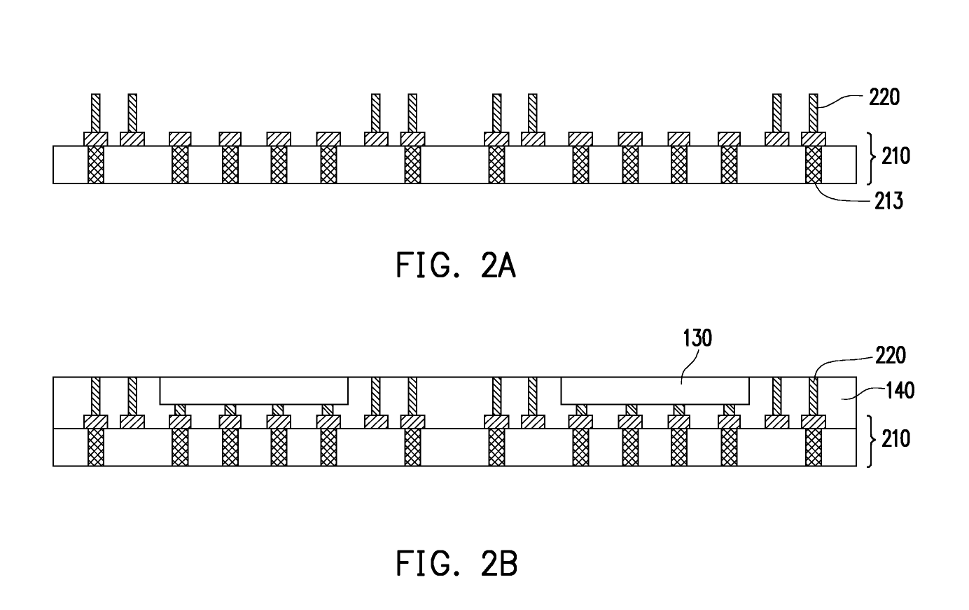

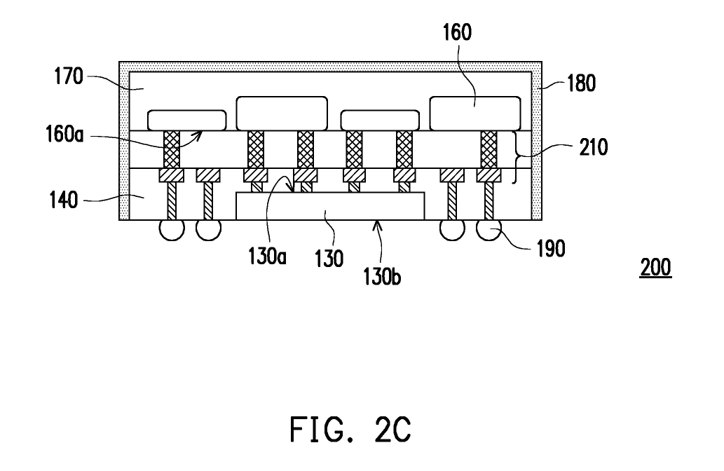

FIG. 2A to FIG. 2C are schematic diagrams of a manufacturing process of a chip package structure according to another embodiment of the invention. A manufacturing process of the chip package structure 200 may be similar to the manufacturing process shown in FIG. 1A to FIG. 1L. Components having same or similar functions may be denoted by same or similar referential numbers. Descriptions of said components may be omitted for brevity. Differences in manufacturing the chip package structure 200 are described in following paragraphs.

Referring to FIG. 2A, a first circuit structure 210 is provided. The first circuit structure 210 has a plurality of pre-fonnrmed through pillars 220. The first circuit structure 210 has a plurality of conductive vias 213. The plurality of conductive vias 213 are used to electrically connect the chips 130 and the electronic devices 160 correspondingly disposed on two opposite sides of the first circuit structure 210. The first circuit structure 210 may be an Embedded Trace Substrate (ETS) having a plurality of through pillars 220, though the invention is not limited thereto.

Then, referring to FIG. 2B, the chips 130 are disposed on the first circuit structure 210. The first encapsulant 140 is formed to encapsulate the chips 130 and the through pillars 220.

After the first encapsulant 140 is formed, the steps described in FIG. 1G to FIG. 1L may be implemented to complete the manufacturing of the chip package structure 200. Referring to FIG. 2C, the chip package structure 200 is different from the chip package structure 100 in the formation of the first circuit structure 210 and the through pillars 220.

The first encapsulant 140 may expose the back surface 130b of the chip 130. The heat dissipation rate of the chip 130 in the chip package structure 200 may be improved.

The first encapsulant 140 and the second encapsulant 170 are separated from each other by the first circuit structure 210.

The conductive terminals 190 may directly contact the through pillars 220.

In summary, in the chip package structure of the invention, the EMI shielding layer is adapted to prevent the EMI from influencing operations of the internal chips, so as to reduce a degree that the EMI influences the chips in operation. Moreover, the chip package structure of the invention may improve a spatial usage rate and effectively integrate the electronic devices of different types. Besides, the manufacturing method of the chip package structure of the invention may effectively improve reliability of the chip package structure and has lower manufacturing cost.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A chip package structure, comprising:
a first circuit structure;
a chip having an active surface facing the first circuit structure;
an electronic device having a connection surface facing the first circuit structure, wherein the chip and the electronic device are correspondingly disposed on two opposite sides of the first circuit structure;
a first encapsulant encapsulating the chip;
a second encapsulant encapsulating the electronic device;
a plurality of through pillars penetrating the first encapsulant and electrically connected to the first circuit structure; and
an electromagnetic interference shielding layer covering the first encapsulant and the second encapsulant.

2. The chip package structure as claimed in claim 1, wherein the chip or the electronic device is grounded through the electromagnetic interference shielding layer.

3. The chip package structure as claimed in claim 1, further comprising:
a second circuit structure disposed on the first encapsulant, wherein two opposite ends of each of the through pillars are correspondingly connected to the first circuit structure and the second circuit structure.

4. The chip package structure as claimed in claim 3, wherein the second circuit structure is exposed through the electromagnetic interference shielding layer.

5. The chip package structure as claimed in claim 3, wherein the second circuit structure is disposed over the chip.

6. The chip package structure as claimed in claim 1, wherein each of the plurality of through pillars have two opposite ends, cross-sectional areas of the two opposite ends are substantially equivalent to each other.

7. The chip package structure as claimed in claim 1, further comprising a plurality of first terminals, wherein the chip is electrically connected to the first circuit structure through the first terminals.

8. The chip package structure as claimed in claim 1, wherein the first encapsulant and the second encapsulant are physically in contact with each other.

9. The chip package structure as claimed in claim 1, wherein the chip has a back surface opposite to the active surface, and the first encapsulant covers the back surface of the chip.

10. The chip package structure as claimed in claim 1, wherein the chip has a back surface opposite to the active surface, and the first encapsulant exposes the back surface of the chip.

11. A method for manufacturing a chip package structure, comprising:
providing a first circuit structure, wherein the first circuit structure has a plurality of through pillars;
disposing a chip on the first circuit structure, wherein the chip has an active surface facing the first circuit structure, and the chip and the through pillars are disposed on a same side of the first circuit structure;
forming a first encapsulant to encapsulate the chip and the through pillars;
disposing an electronic device on the first circuit structure, wherein the electronic device has a connection surface facing the first circuit structure, and the electronic device and the chip are disposed on opposite sides of the first circuit structure;
forming a second encapsulant to encapsulate the electronic device, and
forming an electromagnetic interference shielding layer to cover the first encapsulant and the second encapsulant, wherein the chip or the electronic device is grounded by the electromagnetic interference shielding layer.

12. The method for manufacturing the chip package structure as claimed in claim 11, wherein a distance between the active surface and the connection surface is 50 μm to 500 μm.

13. The method for manufacturing the chip package structure as claimed in claim 11, further comprising:
forming a second circuit structure on the first encapsulant, wherein two opposite ends of each of the through pillars are connected to the first circuit structure and the second circuit structure, respectively.

14. The method for manufacturing the chip package structure as claimed in claim 13, wherein the electromagnetic interference shielding layer exposes the second circuit structure.

15. The method for manufacturing the chip package structure as claimed in claim 11, wherein the second circuit structure is overlapped with the chip.

16. The method for manufacturing the chip package structure as claimed in claim 11, wherein cross-sectional areas of two opposite ends of each of the through pillars are substantially equivalent.

17. The method for manufacturing the chip package structure as claimed in claim 11, further comprising:
forming the first circuit structure on a carrier board before providing the first circuit structure, and forming a plurality of the through pillars on one side of the first circuit structure opposite to the carrier board; and
removing the carrier board before disposing the electronic device on the first circuit structure.

18. The method for manufacturing the chip package structure as claimed in claim 11, wherein the first encapsulant and the second encapsulant contact each other.

19. The method for manufacturing the chip package structure as claimed in claim 11, wherein the chip has a back surface opposite to the active surface, and the first encapsulant covers the back surface of the chip.

20. The method for manufacturing the chip package structure as claimed in claim 11, wherein the chip has a back surface opposite to the active surface, and the first encapsulant exposes the back surface of the chip.
